(19) United States
(12) Patent Application Publication
(10) Pub. No.: US 2015/0366065 A1
(43) Pub. Date: Dec. 17, 2015

(54) DEVICE HAVING A CIRCUIT BOARD AND AN ELECTRONIC CIRCUIT WITH AN ELECTROLYTIC CAPACITOR ARRANGED ON THE CIRCUIT BOARD

(71) Applicant: CONTINENTAL AUTOMOTIVE GMBH, Hannover (DE)

(72) Inventors: NIKOLAUS KERNER, WENZENBACH (DE); THOMAS RIEPL, BAD ABBACH (DE); MICHAEL DECKER, REGENSBURG (DE)

(21) Appl. No.: 14/737,764

(22) Filed: Jun. 12, 2015

(30) Foreign Application Priority Data
Jun. 12, 2014 (DE) 102014211206.0

(51) Int. Cl. H05K 1/18

(52) U.S. Cl. CPC H05K 1/181; H05K 2201/10015; H05K 2201/10053

(57) ABSTRACT

A device has a circuit board and an electronic circuit arranged on the circuit board. The electronic circuit includes an electrolytic capacitor. The electrolytic capacitor is brought to the operating temperature in the case of low temperatures by intrinsic heating as a result of its operation in a detuned circuit.

### CROSS-REFERENCE TO RELATED APPLICATION

This application claims the priority, under 35 U.S.C. §119, of German patent application DE 10 2014 211 206.0, filed Jun. 12, 2014; the prior application is herewith incorporated by reference in its entirety.

### BACKGROUND OF THE INVENTION

### Field of the Invention

Electrolytic capacitors are used in many electronic circuits. The intrinsic electrical resistance of the electrolytic capacitors is an important design criterion for the electronic circuits. Due to the principle of electrolytic capacitors, this intrinsic resistance is however greatly dependent upon temperature. In particular, the intrinsic resistance increases as the temperature decreases. A tenfold increase in the intrinsic resistance in the case of −40° C. in comparison to the intrinsic resistance at room temperature can be regarded as a typical value change.

The general electrical characteristic values of capacitors are described in the technical application in the international field by means of the framework specification IEC 60384-1 that appeared in Germany as DIN EN 60384-1 in February 2002.

They are described by means of an idealized series equivalent circuit diagram as is illustrated in FIG. 1, in which:
C, indicates the capacitance of the electrolytic capacitor;
R_{Leak}, indicates the parallel resistance with respect to the ideal capacitor that represents the residual current (leakage current) of the electrolytic capacitor;
R_{ESR}, indicates the equivalent series resistance. It summarizes the ohmic losses of the component. This effective resistance is generally referred to as only “ESR” (Equivalent Series Resistance);
L_{ESL}, indicates the equivalent series inductance. It summarizes the inductivity of the component and is generally referred to as only “ESL” (Equivalent Series Inductivity L).

The impedance Z, or apparent resistance Z, of an electrolytic capacitor consequently likewise increases as the temperature decreases. The diagram illustrated in FIG. 2 demonstrates the typical behavior.

In order to alleviate this problem, a first approach to solve the problem is to use larger capacitors. Larger structures have a lower intrinsic resistance in comparison to smaller structures.

Alternatively, two smaller capacitors are frequently connected in parallel. With regard to the electrical aspect, this means a parallel connection of the intrinsic resistance and consequently a corresponding reduction.

However, the two solutions require more installation space and are also more expensive.

A further option is to use electrolytic capacitors that comprise special electrolytes that have an improved temperature behavior. Those electrolytic capacitors are, however, generally likewise considerably more expensive in comparison to electrolytic capacitors that comprise conventional electrolytes.

U.S. Pat. No. 5,373,418 and its counterpart European patent EP 0 449 640 B1 describe a device having a circuit board and an electronic circuit that is arranged on the circuit board, said electronic circuit comprising an electrolytic capacitor, wherein at least one power electronics component is arranged on the circuit board, and wherein the electrolytic capacitor is arranged adjacent to the at least one power electronics component on the circuit board.

Published patent application US 2012/0281335 A1 describes device having a circuit board and an electronic circuit that is arranged on said circuit board and that comprises an electrolytic capacitor, wherein a heating element is arranged on or adjacent to the capacitor, and wherein the device comprises a temperature sensor that monitors the temperature of the electrolytic capacitor.

### SUMMARY OF THE INVENTION

It is accordingly an object of the invention to provide an electrolytic capacitor and also a device with a circuit board and an electronic circuit on the circuit board, wherein the circuit includes an electrolytic capacitor which overcomes the above-mentioned and other disadvantages of the heretofore-known devices and methods of this general type and which provides for a simple and cost-effective solution.

With the foregoing and other objects in view there is provided, in accordance with the invention, a circuit device, comprising:
a circuit board;
an electronic circuit arranged on said circuit board, said electronic circuit including an electrolytic capacitor and having a part circuit;
a controllable switch connected between said electrolytic capacitor and said part circuit for selectively connecting said part circuit via said controllable switch to said electrolytic capacitor;
a control circuit configured to close said controllable switch on occasion of temperatures below a predefined operating temperature of said electrolytic capacitor and to open said controllable switch on occasion of temperatures above the predefined operating temperature.

In other words, the objects are achieved by virtue of the device having a circuit board and an electronic circuit that is arranged on said circuit board, said electronic circuit comprising an electrolytic capacitor, wherein the electronic circuit comprises a part circuit that can be connected by way of a controllable switch to the electrolytic capacitor, and wherein the device comprises a first control circuit that closes the controllable switch in the case of temperatures below a predefined operating temperature of the electrolytic capacitor and re-opens said controllable switch in the case of the temperatures above this operating temperature. The control circuit comprises for this purpose a temperature sensing device that can detect or determine the temperature of the electrolytic capacitor.

In a first advantageous embodiment, the part circuit, or partial circuit, forms a resonance circuit with the electrolytic capacitor. The resonant circuit is detuned in the case of temperatures below the predefined operating temperature of the electrolytic capacitor.

In a second advantageous embodiment of the part circuit, it is a switching element that detunes the electronic circuit comprising the electrolytic capacitor.

The electrolytic capacitor is loaded by means of these measures in accordance with the invention when starting up the electronic circuit at low temperatures. As a consequence, a dissipation of power occurs as a result of the intrinsic electrical resistance in the capacitor. This energy causes the temperature of the capacitor to rise. If this start-up operation of the capacitor is sufficiently long, the temperature of the capacitor can increase sufficiently to a value where the intrinsic electrical resistance or the impedance or apparent resistance drops to a value that is necessary for the actual function of the circuit.

In all cases, the process of heating the electrolytic capacitor is terminated by opening the switch or switching off the heating once the operating temperature is achieved.

Other features which are considered as characteristic for the invention are set forth in the appended claims.

Although the invention is illustrated and described herein as embodied in a device having a circuit board and an electronic circuit with a novel electrolytic capacitor arranged on the circuit board, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a schematic diagram of an idealized equivalent circuit;

FIG. 2 is a graph showing the behavior of the impedance; and

FIG. 3 is a schematic illustrating various labeled parameters of a capacitor.

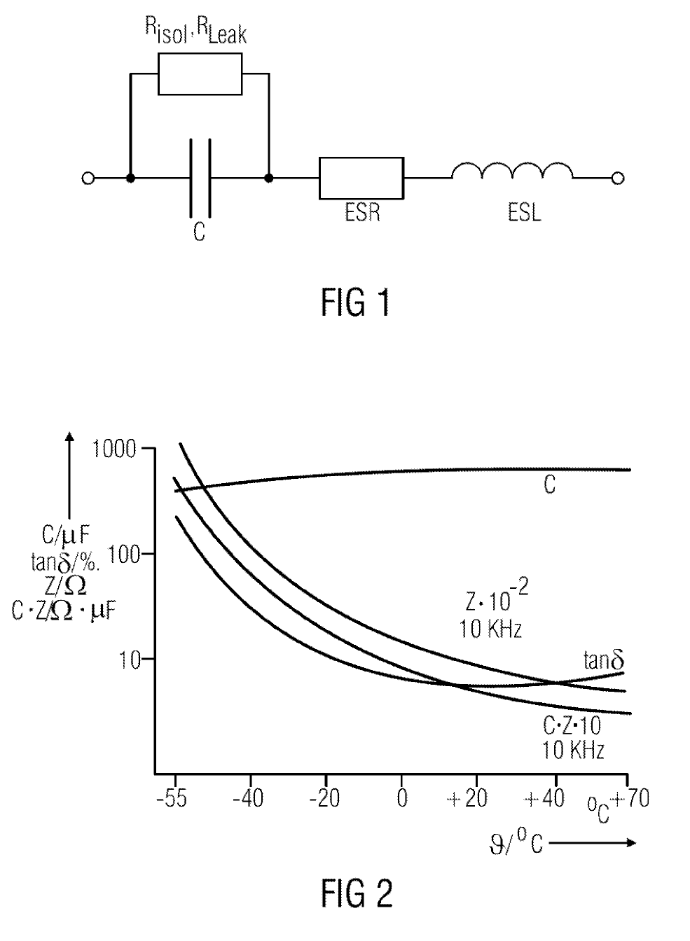

### DETAILED DESCRIPTION OF THE INVENTION

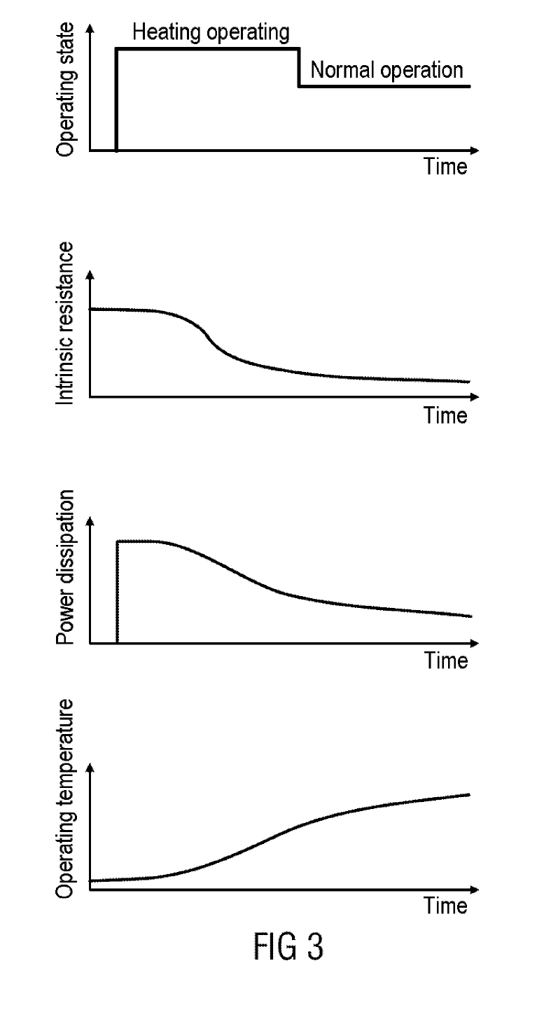

Referring now once more to the drawing and, particularly, to FIG. 3 thereof, there is illustrated, in a series of time diagrams and in a schematic view, the progression of the intrinsic resistance of the capacitor, the progression of the power dissipation of the electronic circuit and its operating temperature (BE-temperature) during a heating operating and during a subsequent normal operation.

It is seen that the intrinsic resistance of the capacitor decreases during the heating operation and reaches a near steady state towards the end of the heating operation and the following normal operation. The power dissipation, or power loss, behaves quite similarly to the resistance. That is, the power loss starts to decrease during the heating operation and nearly flattens out during normal operation. The operating temperature of the capacitor behaves inversely. It increases appreciably during the heating operation and flattens out to increase more slowly during normal operation.

1. A circuit device, comprising:
a circuit board;
an electronic circuit arranged on said circuit board, said electronic circuit including an electrolytic capacitor and having a part circuit;
a controllable switch connected between said electrolytic capacitor and said part circuit for selectively connecting said part circuit via said controllable switch to said electrolytic capacitor;
a control circuit configured to close said controllable switch on occasion of temperatures below a predefined operating temperature of said electrolytic capacitor and to open said controllable switch on occasion of temperatures above the predefined operating temperature.

2. The device according to claim 1, wherein said part circuit together with said electrolytic capacitor forms a resonance circuit which is detuned in the case of temperatures below the predefined operating temperature of the electrolytic capacitor.

3. The device according to claim 1, wherein said part circuit is a switching element configured to detune said electronic circuit with said electrolytic capacitor.
